(19) United States
(12) Patent Application Publication
(10) Pub. No.: US 2014/0357073 A1
(43) Pub. Date: Dec. 4, 2014

(54) SYSTEMS AND METHODS FOR FABRICATING GATE STRUCTURES FOR SEMICONDUCTOR DEVICES

(71) Applicant: GLOBALFOUNDRIES Inc., Grand Cayman (KY)

(72) Inventors: Hongxiang MO, Malta, NY (US); Nam Sung KIM, Watervliet, NY (US)

(21) Appl. No.: 13/909,184

(22) Filed: Jun. 4, 2013

(51) Int. Cl. H01L 21/28

(52) U.S. Cl. CPC H01L 21/28123
USPC 438/595

(57) ABSTRACT

A method includes providing a gate structure with at least one side wall and a bottom. At least one first spacer layer is formed over the at least one side wall. An offset spacer layer is formed over the at least one first spacer layer and the bottom. A bottom portion of the offset spacer layer is selectively removed to expose the bottom.

### FIELD OF THE INVENTION

The present invention generally relates to semiconductor devices and methods of fabricating semiconductor devices, and more particularly, to methods of fabricating gate structures for semiconductor devices.

### BACKGROUND OF THE INVENTION

A finished gate structure (such as a finished gate or transistor gate) is the transistor terminal that modulates channel conductivity. Two principle approaches for forming semiconductor device gate structures are the gate-first and gate-last process approaches.

During fabrication of gate structures for, for instance, complementary metal-oxide-semiconductor (CMOS) technology, gate-first fabrication has traditionally been employed. In a gate-first fabrication approach, a conductor is provided over a gate dielectric, and then patterned (i.e., etched) to form one or more gate structures. After forming the gate structures, source, and drain features of the semiconductor devices are provided.

More recently, the gate-last approach (or replacement metal gate (RMG) approach), has been employed. In the gate-last approach, a sacrificial (or dummy) gate material is provided and patterned (i.e., etched) to define one or more sacrificial gates. The one or more sacrificial gates are subsequently replaced with, for instance, a metal gate, after source and drain features of the devices have been formed. The sacrificial gate material holds the position for the subsequent metal gate to be formed. For instance, an amorphous silicon (a-Si) or polysilicon sacrificial gate may be patterned and used during initial processing until high-temperature annealing to activate the source and drain features has been completed. Subsequently, the a-Si or polysilicon may be removed and replaced with the final metal gate.

Although beneficial in certain aspects, conventional gate-last processing may be susceptible to gate length enlargement due to an etching process defining the sacrificial gate such that the sacrificial gate may become longer than a printed gate length. Such enlargement of the gate may increase a direct overlap capacitance as well as gate to contact parasitic capacitance. It may also increase a total overlap capacitance in the MOSFET and increase total loading capacitance of the relevant circuit. The parasistic capacitance of the circuit increase may cause slower ring oscillator (RO) speed and eventually lower circuit working frequency. With higher effective capacitance (Ceff) of RO, circuit AC performance may degraded and there may be more power consumption during dynamic operation.

Accordingly, a need exists for improved systems and methods for forming semiconductor device gate structures.

### BRIEF SUMMARY

The shortcomings of the prior art are overcome and advantages are provided through the provision, in one aspect, of a method which includes providing a gate structure with at least one sidewall and a bottom. At least one first spacer layer is formed over the at least one sidewall. An offset spacer layer is formed over the at least one first spacer layer and the bottom. A bottom portion of the offset spacer layer is selectively removed to expose the bottom.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 is a partial elevational view of an example of a intermediate structure obtained during a gate-last semiconductor device fabrication approach of a conventional CMOS, in accordance with one or more aspects of the present invention;

FIG. 2 depicts the intermediate structure of FIG. 1 after removal of a portion of a protective spacer layer, in accordance with one or more aspects of the present invention;

FIG. 3 depicts the intermediate structure of FIG. 2 after the deposition of an offset spacer layer, in accordance with one or more aspects of the present invention; and

FIG. 4 depicts the intermediate structure of FIG. 3 after the removal of a portion of the offset spacer layer, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions, and/or arrangements within the spirit and/or scope of the underlying inventive concepts will be apparent to those skilled in the art from this disclosure.

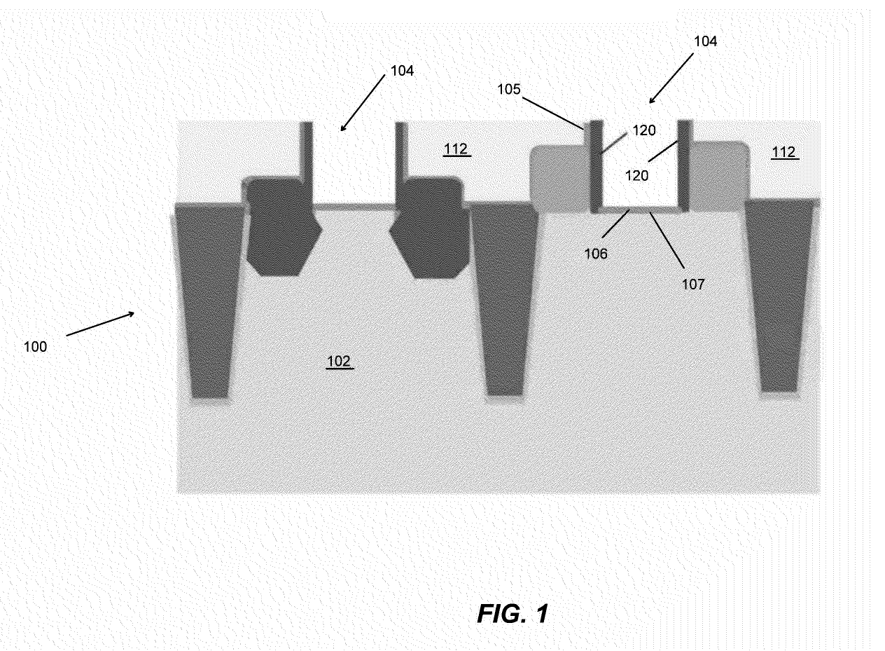

Referring to FIG. 1, a partial side elevational view of an intermediate structure obtained during gate-last fabrication (e.g., of a 20 nm replacement metal gate (RMG)) a semiconductor device, such as a semiconductor device comprising multiple MOSFETs, is depicted. An intermediate structure 100 includes a substrate 102. Multiple gate structures 104 are illustrated, which in one embodiment may be sacrificial gate structures residing above substrate 102 in an intermediate stage of a gate-last semiconductor device fabrication approach. A flowable filling oxide 112 is located between the gate structures. The various layers and structures of intermediate structure 100 depicted in FIG. 1 may be formed using a variety of different materials, and a variety of fabrication techniques, such as chemical-vapor deposition (CVD), atomic layer deposition (ALD), physical vapor deposition (PVD), or plasma-enhanced versions of such processes. The thicknesses of the depicted structures and layers may also vary, depending upon the particular application.

Intermediate structure 100 is depicted in FIG. 1 after chemical mechanical planarization thereof and gate structure 104 (e.g., a dummy polysilicon gate) has been selectively etched as per conventional replacement metal gate processes. By way of example, substrate 102 may be a silicon substrate, and gate structure 104 may be a sacrificial gate structure which includes a sacrificial material, such as polysilicon. As a specific example, the height of sacrificial gate structure 104 may be approximately 40 nanometers (nm) while a width of a replacement metal gate may be 30 nm. Gate structure 104 may include sidewalls 105 and a bottom 106 abutting a top portion 107 of substrate 102. Sidewall portions 120 may abut sidewalls 105 and may be formed of a nitride spacer layer.

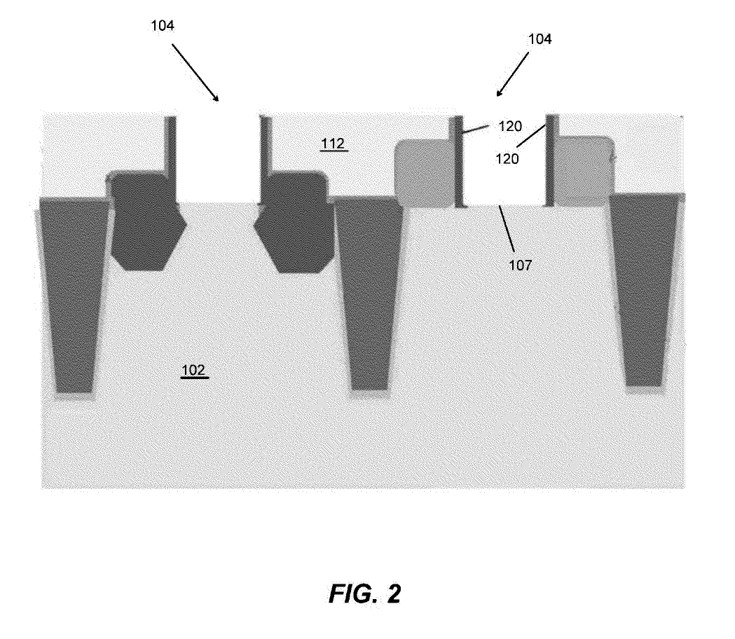

As illustrated in FIG. 2, one or more process operations (e.g., etching) may be performed to remove portions of gate structure 104 (e.g., a poly gate) and some or all of bottom 106 (e.g., an IO oxide layer). For example, sidewall portions 120 may be reduced in thickness due to low selectivity during the process operations while bottom 106 may be completely removed by such process. In one illustrative example, portions of gate structure 104 and bottom 106 may be removed by wet chemical and dry etch process, such as reactive ion etching using fluorine-based chemistry involving process gases such as tetrafluoromethane (CF₄), trifluoromethane (CHF₃), sulfur hexafluoride (SF₆). In another example, sidewall portions 120 may include a nitride oxide which is oxidized during the process and is removed by high dielectric constant (K) (e.g., 10-20) metal pre-cleaning process.

The removal of portions of sidewall portions 120, as depicted in FIG. 2 relative to FIG. 1, may result in a gate length enlargement issue as described above. For example, a final N-type and P-type MOSFET device physical gate length could become about 6 nanometers (nm) longer than a printed gate length. In particular, as indicated above during the etching of gate structure 104 and bottom 106, sidewall portions 120 may be reduced in thickness. The gate length may expand due to this decrease in a thickness in sidewall portions 120 which may result in a final gate (e.g., after the deposition of a metal layer) longer than a designed gate length, which may also be referred to as “Gate Blow Up”. Such Gate Blow Up may cause an NFET and PFET overlap capacitance (Cov) increase due to closer gate and contact. Consequently, a parasitic capacitance of the circuit may go up and cause slower ring oscillator (RO) speed and eventually lower circuit working frequency.

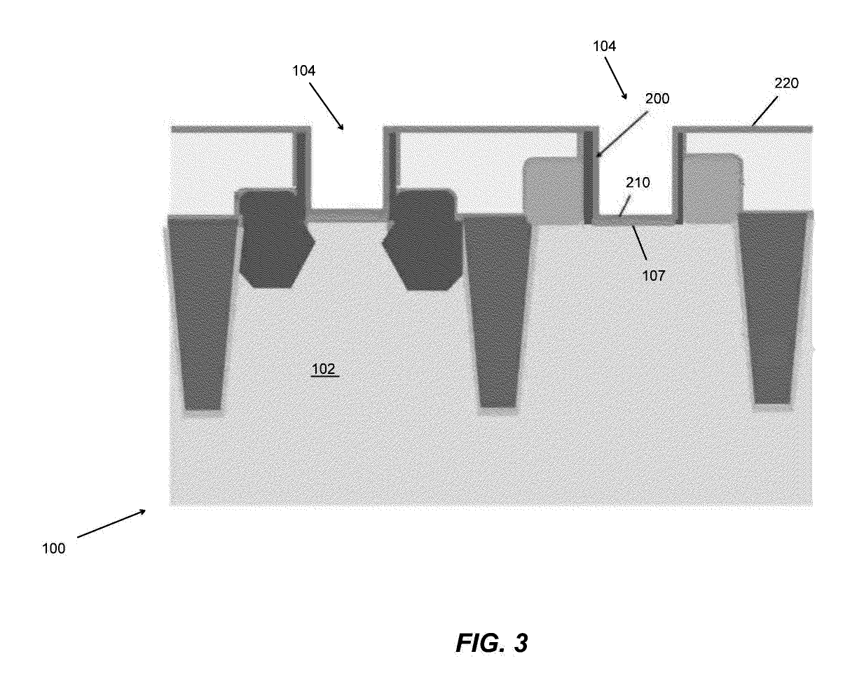

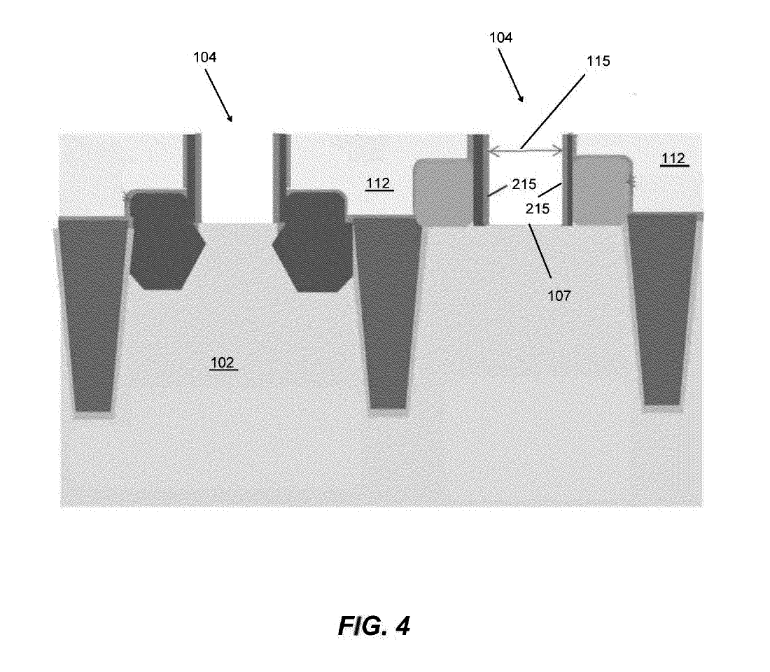

As depicted in FIG. 3, an offset spacer layer 200 may be provided (e.g., via chemical-vapor deposition, atomic layer deposition, physical vapor deposition, or plasma-enhanced versions of such processes) over intermediate structure 100, including sidewall portions 120. As depicted in FIGS. 3-4, a bottom portion 210 of spacer layer 200 may be removed via a dry reactive ion etch, for example, to expose top portion 107 while leaving offset sidewall portions 215. A top portion 220 of spacer layer 200 may also be removed via this method. The addition of offset sidewall portions 215 of spacer layer 200 may avoid the Gate Blow Up issue described above by providing additional spacer material to make up for any reduced thickness of sidewall portions 120. For example, such spacer (e.g., offset sidewall portions 215) may provide 3 nm on each side of sacrificial gate structure 104 to make up for the removal of portion (i.e., reduction in thickness) of sidewall portions 120, which would otherwise result in a Gate Blow Up of 6 nm. The thickness of the spacer on each side of sacrificial gate structure 104 could be adjusted for different RO Ceff (effective capacitance) targeting. An optimal gate length 115 may thus be provided.

The process of adding sidewall portions 215 of spacer layer 200 may be adjusted to provide more or less spacer material (e.g., offset sidewall portions 215) depending on a particular situation. The thickness of sidewall portions 215 may affect the parasitic capacitance between a MOSFET gate (e.g., gate structure 104) and a contact to a MOSFET source and drain. The thicker sidewall portions 215 are, the lower the parasitic capacitance becomes. The parasitic capacitance is part of the total capacitance. Particularly in a RO circuit, it is a part of the Ceff. Lower Ceff improves RO performance, and thus improves performance of an entire circuit.

Metal may be deposited after the formation of offset sidewall portions 215 to form a high-K/metal gate at the location of sacrificial gate material 104. Such high dielectric constant may be 3 to 4 times higher than silicon dioxide. For example, after a High-K layer is deposited, a metal gate may be deposited (e.g., via a chemical vapor deposition or physical vapor deposition process) to fill into the rest of the gap in the location of gate 104. A Chemical Mechanical Polishing/Planarization (CMP) process may also be utilized to remove a metal layer deposited on top of the structure formed by oxide 112.

The above-described process could be used for MOSFET devices. The method includes, in one aspect, fabricating a semiconductor device by providing a gate structure with one or more layers over the gate. The one or more layers may be one or more protective layers, such as one or more hard masks disposed over the gate structure, which itself may be a sacrificial gate structure within an intermediate structure formed during gate-last semiconductor device fabrication processing. By way of example, the sacrificial gate structure may include a sacrificial material, such as polysilicon. The method further includes forming at least one sidewall spacer over the at least one sidewall and the bottom of the gate structure. A bottom of the spacer may then be removed. An offset spacer may then be deposited over the at least one sidewall spacer to avoid any gate enlargement issues. A bottom of the offset spacer may be removed which may cause a removal of a portion of the at least one sidewall spacer. A High-K layer and metal layer may then be deposited over the gate structure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method, comprising:
providing a gate structure with at least one sidewall and a bottom;
forming at least one first spacer layer over the at least one sidewall;
forming an offset spacer layer over the at least one first spacer layer and the bottom; and
selectively removing a bottom portion of the offset spacer layer to expose the bottom.

2. The method of claim 1, wherein the forming the offset spacer layer comprises depositing the offset spacer layer using one of chemical-vapor deposition (CVD), atomic layer deposition (ALD) and physical vapor deposition (PVD) along the at least one sidewall and the bottom.

3. The method of claim 1, wherein the selectively removing comprises etching a portion of the offset spacer layer.

4. The method of claim 1, wherein the selectively removing comprises etching a bottom portion of the offset spacer layer to expose the bottom.

5. The method of claim 4, wherein the selectively removing comprises selectively etching using a nitrogen trifluoride plasma.

6. The method of claim 1 further comprising forming a metal layer over the offset spacer to form a replacement metal gate.

7. The method of claim 1, wherein a thickness of the offset spacer laterally inward from the at least one first spacer layer is about 3 nanometers.

8. The method of claim 1, wherein the at least one offset spacer layer comprises at least one of silicon nitride and an oxide.

9. The method of claim 1, wherein the gate structure comprises a sacrificial gate structure, and wherein the sacrificial gate structure comprises a sacrificial material, the sacrificial material comprising polysilicon.
